(19) United States
(12) Patent Application Publication
(10) Pub. No.: US 2018/0178929 A1
(43) Pub. Date: Jun. 28, 2018

(54) SPACE-QUALIFIED SOLAR CELL ASSEMBLY COMPRISING SPACE-QUALIFIED SOLAR CELLS SHAPED AS A PORTION OF A CIRCLE

(71) Applicant: SolAero Technologies Corp., Albuquerque, NM (US)

(72) Inventors: Claiborne McPheeters, Albuquerque, NM (US); Daniel Derkacs, Albuquerque, NM (US)

(21) Appl. No.: 15/900,385

(22) Filed: Feb. 20, 2018

Related U.S. Application Data
(63) Continuation-in-part of application No. 14/514,883, filed on Oct. 15, 2014.

(51) Int. Cl. B64G 1/54; B64G 1/44; H01L 31/05; H02S 40/34; H01L 31/041

(52) U.S. Cl. CPC B64G 1/546; B64G 1/443; H01L 31/0512; H02S 40/34; H01L 31/041; H01L 31/0508

(57) ABSTRACT

A space-qualified solar cell assembly comprising a plurality of space-qualified solar cells, each space-qualified solar cell of the plurality of space-qualified solar cells being shaped as a portion of a circle, the portion having at least one curved edge having a shape of the arc of the circumference of said circle and at least one straight edge, the portion having a surface area corresponding to not more than 50% of the surface area of the circle.

This makes it possible to make efficient use of the material of the wafer from which the space-qualified solar cells are produced by reducing waste, while arrangement of the space-qualified solar cells into rectangular unit cells enables construction of substantially rectangular space-qualified solar cell arrays and assemblies that have their surface area covered substantially by space-qualified solar cells with little area unoccupied by space-qualified solar cells.

### REFERENCE TO RELATED APPLICATIONS

The present application is a continuation-in-part of U.S. patent application Ser. No. 14/514,883 filed Oct. 15, 2014, incorporated herein by reference in its entirety.

The present application is related to co-pending U.S. patent application Ser. No. 14/498,071 filed Sep. 26, 2014.

### BACKGROUND OF THE DISCLOSURE

### 1. Field of the Disclosure

The disclosure relates to the field of photovoltaic power devices, and more particularly arrays of discrete solar cells.

### 2. Description of the Related Art

Photovoltaic devices, such as photovoltaic modules or CIC (Solar Cell+Interconnects+Coverglass) devices, comprise one or more individual solar cells arranged to produce electric power in response to irradiation by solar light. Sometimes, the individual solar cells are rectangular, often square. Photovoltaic modules, arrays and devices including one or more solar cells may also be substantially rectangular, for example, based on an array of individual solar cells. Arrays of substantially circular solar cells are known to involve the drawback of inefficient use of the surface on which the solar cells are mounted, due to space that is not covered by the circular solar cells due to the space that is left between adjacent solar cells due to their circular configuration (cf. U.S. Pat. Nos. 4,235,643 and 4,321,417).

However, solar cells are often produced from circular or substantially circular wafers. For example, solar cells for space applications are typically multi junction solar cells grown on substantially circular wafers. These circular wafers are sometimes 100 mm or 150 mm diameter wafers. However, as explained above, for assembly into a solar array (henceforth, also referred to as a solar cell assembly), substantially circular solar cells, which can be produced from substantially circular wafers to minimize wasting wafer material and, therefore, minimize solar cell cost, are often not the best option, due to their low array fill factor, which increases the overall cost of the photovoltaic array or panel and implies an inefficient use of available space. Therefore, the circular wafers are often divided into other form factors to make solar cells. The preferable form factor for a solar cell for space is a rectangle, such as a square, which allows for the area of a rectangular panel consisting of an array of solar cells to be filled 100% (henceforth, that situation is referred to as a “fill factor” of 100%), assuming that there is no space between the adjacent rectangular solar cells. However, when a single circular wafer is divided into a single rectangle, the wafer utilization is low. This results in waste. This is illustrated in FIG. 1, showing how conventionally, out of a circular solar cell wafer 100 a rectangular solar cell 1000 is obtained, leaving the rest of the wafer as waste 1001. This rectangular solar cell 1000 can then be placed side by side with other rectangular solar cells 1000 obtained from other wafers, thereby providing for efficient use of the surface on which the solar cells are placed (i.e., a high fill factor): a large W/m² ratio can be obtained, which depending on the substrate may also imply a high W/kg ratio, of great importance for space applications. That is, closely packed solar cells without any space between the adjacent solar cells is generally preferred, and especially for applications in which W/m² and/or W/kg are important aspects to consider.

Space applications frequently use high efficiency solar cells, including multi junction solar cells and/or III/V compound semiconductor solar cells. High efficiency solar cell wafers are often costly to produce. Thus, the waste that has conventionally been accepted in the art as the price to pay for a high fill factor, that is, the waste that is the result of cutting the rectangular solar cell out of the substantially circular solar cell wafer, can imply a considerable cost.

Thus, the option of using substantially circular solar cells, corresponding to substantially circular solar cell wafers, to produce an array or assembly of space-qualified solar cells, could in some cases become an interesting option. There is a trade-off between maximum use of the original wafer material and the fill factor. FIG. 2 shows how circular wafers can be packed according to a layout for maximum use of space, obtaining a fill factor in the order of 90%. This implies less wafer material is wasted than in the case of the option shown in FIG. 1, but also a less efficient use of the surface on which the solar cells are mounted, due to the lower fill factor. A further problem is that with this kind of layout, the pattern features a hexagonal unit cell 2000 (illustrated with broken lines in FIG. 2), which is non-optimal for producing a rectangular assembly of solar cells. The hexagonal unit cell is inconvenient for producing rectangular arrays of solar cells because the assembly of solar cells will not fit neatly to the edges or boundaries of a rectangular panel.

### SUMMARY OF THE DISCLOSURE

A first aspect of the disclosure relates to a space-qualified solar cell assembly designed for operation at AM0 and at a 1 MeV electron equivalent fluence of at least 5×10¹⁴ e/cm², the assembly comprising a III-V compound semiconductor multijunction solar cell including at least three subcells, including a ceria doped borosilicate glass supporting member that is 3 to 6 mils in thickness attached to each solar cell with a transparent adhesive, wherein a combination of compositions and band gaps of the subcells is designed to maximize efficiency of the solar cell at a predetermined end-of-life (EOL) time period, after initial deployment when the solar cell is deployed in space at AM0 and at an operational temperature in the range of 40 to 70 degrees Centigrade, the predetermined EOL time period comprising at least five years, the space-qualified solar cell assembly comprising a plurality of solar cells, each of said plurality of solar cells being shaped as a portion, such as a sector or segment, of a substantially circular wafer, said portion having at least one curved edge having substantially the shape of an arc of the circumference of the circle and at least one straight edge, and having a surface area corresponding to not more than 50% of the surface area of the circle, that is, the total surface area, of the circle. That is, each of said plurality of space-qualified solar cells has a shape corresponding to the one that is obtained by cutting a substantially circular wafer into at least two pieces, such as according to a sector or segment of the circle defined by the circumference of the substantially circular space-qualified solar cell wafer.

It has been found that by dividing a substantially circular wafer into segments or, maybe preferably, sectors, space-qualified solar cells are obtained that can be packed with a high fill factor while, at the same time, producing a rectangular unit cell, which is preferred in the case of the production of substantially rectangular space-qualified solar cell assemblies. For example, a square unit cell can be appropriate, allowing the unit cells to be rotated, for example, at the edges of the panel, simplifying interconnection. By using such an approach, wafer waste is minimized. Thus, by the division of the substantially circular wafer into portions such as segments or sectors, wafer utilization is maximized and at the same time a high fill factor is obtained in combination with a rectangular unit cell for the solar cell assembly. Thus, the disclosure provides for a flexible system that can often be advantageous to reach a good balance between the cost of the solar cell on the one hand and efficiency in terms of W/m² or W/kg of the space-qualified solar cell assembly on the other hand. The disclosure may be especially useful and advantageous in the context of space-qualified solar cells where the cost of the space-qualified solar cell wafer is high, including many high efficiency space-qualified solar cells, multi junction space-qualified solar cells and III/V compound semiconductor space-qualified solar cells. It provides for relatively low wafer waste, while at the same time providing for a relatively high fill factor, which can also be important, for example, when the total space allowed for a solar panel, such as on a satellite or rooftop, limits the maximum power that can be provided by the solar panel. The disclosure makes it possible to make use also of the material adjacent to the circumference of the circular wafer, without renouncing excessively on the fill factor and without renouncing on a rectangular unit cell. It has been found that it is possible to achieve >90% panel fill factor and to simultaneously achieve >90% wafer utilization, providing for a combined wafer and space utilization efficiency of >81%, if the mathematical product of the two aspects (panel fill factor and wafer utilization) is taken as a basis for calculating efficiency. Of course, in practice, it may be more important to enhance one of the two aspects than the other one, depending on issues such as the cost of wafer material and cost or availability of space.

In some embodiments of the disclosure, one portion of the space-qualified solar cell corresponding to what was originally the circumference of the wafer may be modified to a flat portion or a ‘v’-shaped notch, for example. This is especially the case when the space-qualified solar cells are obtained from a substantially circular wafer having a flat portion or a ‘v’ notch in correspondence with its circumference. This is often the case. When “circular wafers” or ‘circles’ are referred to herein, it is understood that in practice such shapes may be fully circular, but that the principles disclosed apply equally to substantially circular shapes or wafers, as are often used in practice.

In some embodiments of the disclosure, the space-qualified solar cell assembly is made up entirely of this kind of space-qualified solar cell; in other embodiments of the disclosure, the space-qualified solar cell assembly includes also other kinds of space-qualified solar cells, for example, completely circular space-qualified solar cells and/or rectangular space-qualified solar cells. However, for simplicity in terms of layout, assembly and interconnection, it is often preferred to use space-qualified solar cells all having the same shape and/or size.

In some embodiments of the disclosure, the curved edge of said plurality of space-qualified solar cells has a length corresponding to at least 45 degrees, preferably at least 60 degrees, more preferably at least 90 degrees, of the circumference of the circle, and/or a size of at least 10%, preferably at least 25%, of the area of the circle. The use of relatively large space-qualified solar cells can be useful to reduce the amount of work related to assembly and interconnections.

In some embodiments of the disclosure, said plurality of space-qualified solar cells are substantially shaped as sectors of said circle. This option is often preferred, as it has been found practical to implement: it allows for full use of substantially all of the material of the substantially circular wafer and for the production of substantially identical space-qualified solar cells which can then be assembled to form the array using the repetition of a simple basic pattern, without any need to accommodate a large number of differently shaped space-qualified solar cells. The term “substantially” is used to encompass minor variants, such as the cases wherein there is one or more additional flat portions corresponding to the above-mentioned flat portion of the circumference present in many substantially circular wafers used for the production of space-qualified solar cells.

In some embodiments of the disclosure, said plurality of space-qualified solar cells comprises a plurality of space-qualified solar cells substantially shaped as quadrants, that is, as quarters of a substantially circular wafer, with two straight edges at substantially 90 degrees to each other. A circular wafer can be split into four quadrants without substantial waste of material, and the use of quadrants has been found to be beneficial as the quadrants can be fitted into rectangular unit cells with a high fill factor, in the order of 90% or greater than 90%. Of course, a circular wafer can be split into smaller sectors which can, for example, be interconnected to form a quadrant, but this may at least sometimes be inefficient as interconnection implies additional costs. Thus, in many embodiments of the disclosure, it can be preferred to use only quadrants, or at least a substantial number and/or proportion of quadrants.

In some embodiments of the disclosure, said plurality of space-qualified solar cells comprises a plurality of space-qualified solar cells substantially shaped as semicircles. Semicircles may be less attractive than quadrants in what concerns flexibility and/or fill factor, but can nevertheless be used in embodiments of the disclosure.

In some embodiments of the disclosure, said plurality of space-qualified solar cells comprises both space-qualified solar cells shaped as quadrants and space-qualified solar cells shaped as semicircles. For example, in some embodiments of the disclosure, a semicircle and two quadrants can be combined into a unit cell, one example of which is illustrated in FIG. 5. The use of one semicircle instead of two quadrants can serve to limit the number of interconnections.

In some embodiments of the disclosure, a plurality of the space-qualified solar cells are arranged so that a straight edge of one space-qualified solar cell is placed against the straight edge of another one of the space-qualified solar cells. For example, the straight edges can be placed against each other where some unit cells meet.

In some embodiments of the disclosure, the space-qualified solar cells are arranged in a pattern formed by an array of rectangular unit cells, each unit cell encompassing an identical or substantially identical arrangement of at least two space-qualified solar cells. This can be an advantage over the use of tightly packed space-qualified solar cells having a circular shape, that is, shaped as substantially full circles. If one or more substantially fully circular space-qualified solar cells are efficiently fitted into the area of a rectangle, the rectangle being a unit cell useful for building a rectangular array of unit cells, that is, with rows and columns of aligned unit cells, the fill factor will be relatively low (i.e., in the order of 60%), which is a disadvantage. If, on the other hand, the circular unit cells are placed as close together as possible, the unit cell will be hexagonal, as explained in relation to FIG. 2, which is a disadvantage for fitting neatly into a rectangular or substantially rectangular solar cell assembly comprising an array of unit cells. Contrarily, with the present disclosure, it is possible to obtain rectangular unit cells with a rather high fill factor, such as greater than 90%, which fit neatly into a rectangular or substantially rectangular space-qualified solar cell assembly comprising an array of unit cells.

In some embodiments of the disclosure, each unit cell encompasses at least two space-qualified solar cells arranged so that the curved edge of each one of said space-qualified solar cells is placed against the curved edge of another one of said space-qualified solar cells. This provides for a high fill factor of the unit cell and, accordingly, of a rectangular or substantially rectangular space-qualified solar cell assembly made up of a row or array of unit cells, such as an array comprising rows and columns of unit cells.

In some embodiments of the invention, each unit cell encompasses at least two space-qualified solar cells arranged so that a flat portion at a curved edge of one space-qualified solar cell is placed against a flat portion at a curved edge of another one of said space-qualified solar cells. These flat portions can in some embodiments of the invention originate from original flat portions of the wafer, or they can have been added by cropping the space-qualified solar cells at their curved edges.

In some embodiments of the disclosure, the space-qualified solar cells have been obtained by dividing a substantially circular wafer into a plurality of substantially identical portions, such as into substantially identical sectors. Thus, full advantage is taken of the material of the wafer, thereby minimizing the cost per area of space-qualified solar cell. The use of identical portions can simplify the assembly. Preferably, at least the size of the portions is substantially the same, as this provides for substantially identical production of electrical current, which simplifies the interconnection of space-qualified solar cells. Another aspect of the disclosure relates to a method of producing space-qualified solar cells for a space-qualified solar cell assembly designed for operation at AM0 and at a 1 MeV electron equivalent fluence of at least 5×10¹⁴ e/cm², comprising forming a III-V compound semiconductor multijunction solar cell including at least three subcells; attaching a ceria doped borosilicate glass supporting member that is 3 to 6 mils in thickness to each space-qualified solar cell with a transparent adhesive; forming a combination of compositions and band gaps of the space-qualified subcells designed to maximize efficiency of the space-qualified solar cell at a predetermined end-of-life (EOL) time period, after initial deployment when the space-qualified solar cell is deployed in space at AM0 and at an operational temperature in the range of 40 to 70 degrees Centigrade, the EOL comprising at least five years; and dividing at least one substantially circular solar cell wafer into a plurality of portions, each portion being a space-qualified solar cell, at least some of said portions having at least one substantially straight edge and one substantially curved edge corresponding to an arc of the circumference of the solar cell wafer. In some embodiments of the disclosure, said portions are sectors of the circular solar cell wafer, for example quadrants or semicircles, as explained above.

A further aspect of the disclosure relates to a method of producing a space-qualified solar cell assembly, comprising the steps of providing a plurality of space-qualified solar cells with the method described above, and assembling the space-qualified solar cells to provide a substantially rectangular space-qualified solar cell assembly.

In some embodiments of the disclosure, the method comprises the step of arranging the space-qualified solar cells according to a pattern of identical rectangular unit cells arranged in an array forming the substantially rectangular solar cell assembly, each unit cell including an identical arrangement of at least two space-qualified solar cells. In some embodiments of the disclosure, the space-qualified solar cells are substantially identical. The use of substantially identical space-qualified solar cells, or at least of space-qualified solar cells having substantially the same effective surface area, often simplifies the interconnection of space-qualified solar cells, as there is less need to take differences in electrical current production into account.

### BRIEF DESCRIPTION OF THE DRAWINGS

To complete the description and in order to provide for a better understanding of the disclosure, a set of drawings is provided. Said drawings form an integral part of the description and illustrate embodiments of the disclosure, which should not be interpreted as restricting the scope of the disclosure, but just as examples of how the disclosure can be carried out. The drawings comprise the following figures:

FIG. 1 schematically illustrates a prior art arrangement for producing a closely packed solar cell array out of square solar cells obtained from a circular solar cell wafer.

FIG. 2 schematically illustrates how circular solar cells packed to obtain a maximum fill factor imply a hexagonal unit cell for the arrangement of solar cells in an array of solar cells, or a solar cell assembly.

FIG. 3 schematically illustrates how a solar cell assembly can be produced of solar cells consisting of quadrants cut from a circular wafer, in accordance with an embodiment of the disclosure.

FIG. 4 schematically illustrates the unit cell in the embodiment of FIG. 3.

FIG. 5 schematically illustrates a unit cell in an alternative embodiment of the disclosure, based on the use of both quadrants semicircular solar cells.

FIG. 6 schematically illustrates a unit cell based on four quadrants cut from a circular wafer having two flat portions at the circumference.

FIG. 7 schematically illustrates how a square solar cell with cropped corners can be obtained from a circular wafer and fitted into a square unit cell.

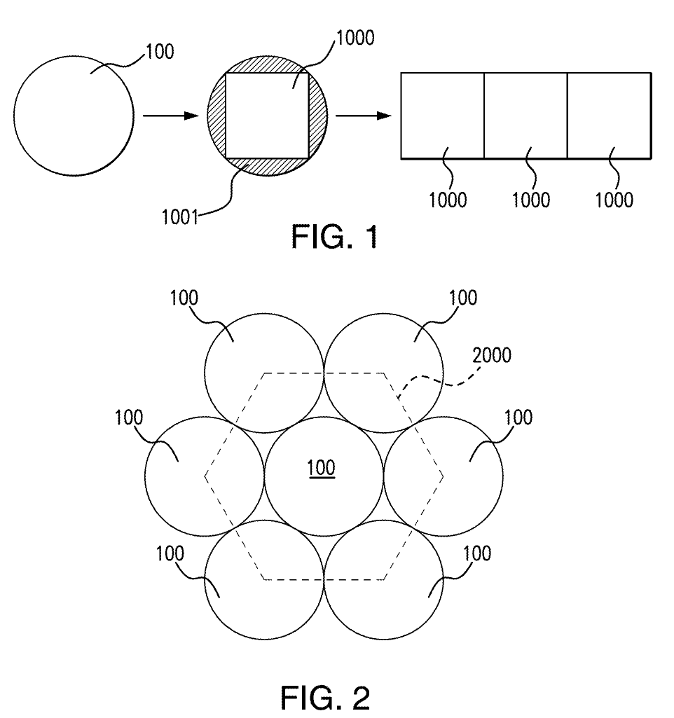

### DETAILED DESCRIPTION

The present disclosure relates to space-qualified solar cell assemblies that generate solar power using space-qualified solar cells, as opposed to using photovoltaic cells, also referred to as terrestrial solar cells, which are predominantly provided by silicon semiconductor technology. Recently, high-volume manufacturing of III-V compound semiconductor multijunction solar cells for space applications has accelerated the development of such technology. Compared to silicon, III-V compound semiconductor multijunction devices have greater energy conversion efficiencies and are generally more radiation resistance, although they tend to be more complex to properly specify and manufacture. Typical commercial III-V compound semiconductor multijunction solar cells have energy efficiencies that exceed 29.5% under one sun, air mass 0 (AM0) illumination, whereas even the most efficient silicon technologies generally reach only about 18% efficiency under comparable conditions. The higher conversion efficiency of III-V compound semiconductor solar cells compared to silicon solar cells is in part based on the ability to achieve spectral splitting of the incident radiation through the use of a plurality of series connected photovoltaic regions with different band gap energies, and accumulating the voltage at a given current from each of the regions.

Typical III-V compound semiconductor solar cells are fabricated on a semiconductor wafer in vertical, multijunction structures or stacked sequence of solar subcells, each subcell formed with appropriate semiconductor layers and including a p-n photoactive junction. Each subcell is designed to convert photons over different spectral or wavelength bands to electrical current. After the sunlight impinges on the front of the solar cell, photons pass through the subcells, with each subcell being designed for photons in a specific wavelength band. After passing through a subcell, the photons that are not absorbed and converted to electrical energy propagate to the next subcells, where such photons are intended to be captured and converted to electrical energy.

The individual solar cells or wafers are then disposed in horizontal arrays, with the individual solar cells connected together in an electrical series circuit. The shape and structure of an array, as well as the number of cells it contains, are determined in part by the desired output voltage and current needed by the payload or subcomponents of the payload, the amount of electrical storage capacity (batteries) on the spacecraft, and the power demands of the payloads during different orbital configurations.

A solar cell designed for use in a space vehicle (such as a satellite, space station, or an interplanetary mission vehicle), has a sequence of subcells with compositions and band gaps which have been optimized to achieve maximum energy conversion efficiency for the AM0 solar spectrum in space. The AM0 solar spectrum in space is notably different from the AM1.5 solar spectrum at the surface of the earth, and accordingly terrestrial solar cells are designed with subcell band gaps optimized for the AM1.5 solar spectrum.

In satellite and other space related applications, the size, mass and cost of a space vehicle or satellite power system are dependent on the power and energy conversion efficiency of the solar cells used. Putting it another way, the size of the payload and the availability of on-board services are proportional to the amount of power provided. Thus, as payloads use increasing amounts of power as they become more sophisticated, and as missions and applications anticipated for five, ten, twenty or more years become more prevalent, the power-to-weight ratio (measured in watts per kg) and lifetime efficiency of a solar cell array or panel become increasingly more important. There is increasing interest in not only the amount of power provided at initial deployment, but over the entire service life of the satellite system, or in terms of a design specification, the amount of power provided at the “end of life” (EOL) which is affected by the radiation exposure of the solar cell over time in a space environment.

Space applications frequently use high efficiency multijunction III/V compound semiconductor solar cells. Compound semiconductor solar cell wafers are often costly to produce. Thus, the waste that has conventionally been accepted in the art when cutting the rectangular solar cell out of the substantially circular solar cell wafer can imply considerable cost.

A solar cell designed for use in a space vehicle (such as a satellite, space station, or an interplanetary mission vehicle), has a sequence of subcells with compositions and band gaps which have been optimized to achieve maximum energy conversion efficiency for the AM0 solar spectrum in space. The AM0 solar spectrum in space is notably different from the AM1.5 solar spectrum at the surface of the earth, and accordingly terrestrial solar cells are designed with subcell band gaps optimized for the AM1.5 solar spectrum.

There are substantially more rigorous qualification and acceptance testing protocols used in the manufacture of space solar cells compared to terrestrial cells, to ensure that space solar cells can operate satisfactorily at the wide range of temperatures and temperature cycles encountered in space. These testing protocols include (i) high-temperature thermal vacuum bake-out; (ii) thermal cycling in vacuum (TVAC) or ambient pressure nitrogen atmosphere (APTC); and in some applications (iii) exposure to radiation equivalent to that which would be experienced in the space mission, and measuring the current and voltage produced by the cell and deriving cell performance data.

As used in this disclosure and claims, the term “space-qualified” shall mean that the electronic component (i.e., the solar cell) provides satisfactory operation under the high temperature and thermal cycling test protocols. The exemplary conditions for vacuum bake-out testing include exposure to a temperature of +100° C. to +135° C. (e.g., about +100° C., +110° C., +120° C., +125° C., +135° C.) for 2 hours to 24 hours, 48 hours, 72 hours, or 96 hours; and exemplary conditions for TVAC and/or APTC testing that include cycling between temperature extremes of −180° C. (e.g., about −180° C., −175° C., −170° C., −165° C., −150° C., −140° C., −128° C., −110° C., −100° C., −75° C., or −70° C.) to +145° C. (e.g., about +70° C., +80° C., +90° C., +100° C., +110° C., +120° C., +130° C., +135° C., or +145° C.) for 600 to 32,000 cycles (e.g., about 600, 700, 1500, 2000, 4000, 5000, 7500, 22000, 25000, or 32000 cycles), and in some space missions up to +180° C. See, for example, Fatemi et al., “Qualification and Production of Emcore ZTJ Solar Panels for Space Missions,” Photovoltaic Specialists Conference (PVSC), 2013 IEEE 39th (DOI: 10. 1109/PVSC 2013 6745052). Such rigorous testing and qualifications are not generally applicable to terrestrial solar cells and solar cell arrays.

Conventionally, such measurements are made for the AM0 spectrum for “one-sun” illumination, but for PV systems which use optical concentration elements, such measurements may be made under concentrations such as 2×, 100×, or 1000× or more.

The space solar cells and arrays experience a variety of complex environments in space missions, including the vastly different illumination levels and temperatures seen during normal earth orbiting missions, as well as even more challenging environments for deep space missions, operating at different distances from the sun, such as at 0.7, 1.0 and 3.0 AU (AU meaning astronomical units). The photovoltaic arrays also endure anomalous events from space environmental conditions, and unforeseen environmental interactions during exploration missions. Hence, electron and proton radiation exposure, collisions with space debris, and/or normal aging in the photovoltaic array and other systems could cause suboptimal operating conditions that degrade the overall power system performance, and may result in failures of one or more solar cells or array strings and consequent loss of power.

A further distinctive difference between space solar cell arrays and terrestrial solar cell arrays is that a space solar cell array utilizes welding and not soldering to provide robust electrical interconnections between the solar cells, while terrestrial solar cell arrays typically utilize solder for electrical interconnections. Welding is required in space solar cell arrays to provide the very robust electrical connections that can withstand the wide temperature ranges and temperature cycles encountered in space such as from −175° C. to +180° C. In contrast, solder joints are typically sufficient to survive the rather narrow temperature ranges (e.g., about −40° C. to about +50° C.) encountered with terrestrial solar cell arrays.

A further distinctive difference between space solar cell arrays and terrestrial solar cell arrays is that a space solar cell array utilizes silver-plated metal material for interconnection members, while terrestrial solar cells typically utilize copper wire for interconnects. In some embodiments, the interconnection member can be, for example, a metal plate. Useful metals include, for example, molybdenum; a nickel-cobalt ferrous alloy material designed to be compatible with the thermal expansion characteristics of borosilicate glass such as that available under the trade designation KOVAR from Carpenter Technology Corporation; a nickel iron alloy material having a uniquely low coefficient of thermal expansion available under the trade designation Invar, FeNi36, or 64FeNi; or the like.

An additional distinctive difference between space solar cell arrays and terrestrial solar cell arrays is that space solar cell arrays typically utilize an aluminum honeycomb panel for a substrate or mounting platform. In some embodiments, the aluminum honeycomb panel may include a carbon composite face sheet adjoining the solar cell array. In some embodiments, the face sheet may have a coefficient of thermal expansion (CTE) that substantially matches the CTE of the bottom germanium (Ge) layer of the solar cell that is attached to the face sheet. Substantially matching the CTE of the face sheet with the CTE of the Ge layer of the solar cell can enable the array to withstand the wide temperature ranges encountered in space without the solar cells cracking, delaminating, or experiencing other defects. Such precautions are generally unnecessary in terrestrial applications.

Thus, a further distinctive difference of a space solar cell from a terrestrial solar cell is that the space solar cell must include a cover glass over the semiconductor device to provide radiation resistant shielding from particles in the space environment which could damage the semiconductor material. The cover glass is typically a ceria doped borosilicate glass which is typically from three to six mils in thickness and attached by a transparent adhesive to the solar cell.

In summary, it is evident that the differences in design, materials, and configurations between a space-qualified III-V compound semiconductor solar cell and subassemblies and arrays of such solar cells, on the one hand, and silicon solar cells or other photovoltaic devices used in terrestrial applications, on the other hand, are so substantial that prior teachings associated with silicon or other terrestrial photovoltaic system are simply unsuitable and have no applicability to the design configuration of space-qualified solar cells and arrays. Indeed, the design and configuration of components adapted for terrestrial use with its modest temperature ranges and cycle times often teach away from the highly demanding design requirements for space-qualified solar cells and arrays and their associated components.

The assembly of individual solar cells together with electrical interconnects and the cover glass form a so-called “CIC” (Cell-Interconnected-Cover glass) assembly, which are then typically electrically connected to form an array of series-connected solar cells. The solar cells used in many arrays often have a substantial size; for example, in the case of the single standard substantially “square” solar cell trimmed from a 100 mm wafer with cropped corners, the solar cell can have a side length of seven cm or more.

The radiation hardness of a solar cell is defined as how well the cell performs after exposure to the electron or proton particle radiation which is a characteristic of the space environment. A standard metric is the ratio of the end of life performance (or efficiency) divided by the beginning of life performance (EOL/BOL) of the solar cell. The EOL performance is the cell performance parameter after exposure of that test solar cell to a given fluence of electrons or protons (which may be different for different space missions or orbits). The BOL performance is the performance parameter prior to exposure to the particle radiation.

Charged particles in space could lead to damage to solar cell structures, and in some cases, dangerously high voltage being established across individual devices or conductors in the solar array. These large voltages can lead to catastrophic electrostatic discharging (ESD) events. Traditionally for ESD protection the backside of a solar array may be painted with a conductive coating layer to ground the array to the space plasma, or one may use a honeycomb patterned metal panel which mounts the solar cells and incidentally protects the solar cells from backside radiation.

The radiation hardness of the semiconductor material of the solar cell itself is primarily dependent on a solar cell's minority carrier diffusion length (Lₘᵢₙ) in the base region of the solar cell (the term “base” region referring to the p-type base semiconductor region disposed directly adjacent to an n-type “emitter” semiconductor region, the boundary of which establishes the p-n photovoltaic junction). The less degraded the parameter Lₘᵢₙ is after exposure to particle radiation, the less the solar cell performance will be reduced. A number of strategies have been used to either improve Lₘᵢₙ, or make the solar cell less sensitive to Lₘᵢₙ reductions. Improving Lₘᵢₙ has largely involved including a gradation in dopant elements in the semiconductor base layer of the subcells so as to create an electric field to direct minority carriers to the junction of the subcell, thereby effectively increasing Lₘᵢₙ. The effectively longer Lₘᵢₙ will improve the cell performance, even after the particle radiation exposure. Making the cell less sensitive to Lₘᵢₙ reductions has involved increasing the optical absorption of the base layer such that thinner layers of the base can be used to absorb the same amount of incoming optical radiation.

Another consideration in connection with the manufacture of space solar cell arrays is that conventionally, solar cells have been arranged on a support and interconnected using a substantial amount of manual labor. For example, first individual CICs are produced with each interconnect individually welded to the solar cell, and each cover glass individually mounted. Then, these CICs are connected in series to form strings, generally in a substantially manual manner, including the welding steps from CIC to CIC. Then, these strings are applied to a panel substrate and electrically interconnected in a process that includes the application of adhesive, wiring, etc. All of this has traditionally been carried out in a manual and substantially artisanal manner.

The energy conversion efficiency of multijunction solar cells is affected by such factors as the number of subcells, the thickness of each subcell, the composition and doping of each active layer in a subcell, and the consequential band structure, electron energy levels, conduction, and absorption of each subcell, as well as the effect of its exposure to radiation in the ambient environment over time. The identification and specification of such design parameters is a non-trivial engineering undertaking, and would vary depending upon the specific space mission and customer design requirements. Since the power output is a function of both the voltage and the current produced by a subcell, a simplistic view may seek to maximize both parameters in a subcell by increasing a constituent element, or the doping level, to achieve that effect. However, in reality, changing a material parameter that increases the voltage may result in a decrease in current, and therefore a lower power output. Such material design parameters are interdependent and interact in complex and often unpredictable ways, and for that reason are not “result effective” variables that those skilled in the art confronted with complex design specifications and practical operational considerations can easily adjust to optimize performance.

Moreover, the current (or more precisely, the short circuit current density J_{sc}) and the voltage (or more precisely, the open circuit voltage V_{oc}) are not the only factors that determine the power output of a solar cell. In addition to the power being a function of the short circuit density (J_{sc}), and the open circuit voltage (V_{oc}), the output power is actually computed as the product of V_{oc} and J_{sc}, and a Fill Factor (FF). As might be anticipated, the Fill Factor parameter is not a constant, but in fact may vary at a value between 0.5 and somewhat over 0.85 for different arrangements of elemental compositions, subcell thickness, and the dopant level and profile. Although the various electrical contributions to the Fill Factor such as series resistance, shunt resistance, and ideality (a measure of how closely the semiconductor diode follows the ideal diode equation) may be theoretically understood, from a practical perspective the actual Fill Factor of a given subcell cannot always be predicted, and the effect of making an incremental change in composition or band gap of a layer may have unanticipated consequences and effects on the solar subcell semiconductor material, and therefore an unrecognized or unappreciated effect on the Fill Factor. Stated another way, an attempt to maximize power by varying a composition of a subcell layer to increase the V_{oc} or J_{sc} or both of that subcell, may in fact not result in high power, since although the product V_{oc} and J_{sc} may increase, the FF may decrease and the resulting power also decrease. Thus, the V_{oc} and J_{sc} parameters, either alone or in combination, are not necessarily “result effective” variables that those skilled in the art confronted with complex design specifications and practical operational considerations can easily adjust to optimize performance.

Furthermore, the fact that the short circuit current density (J_{sc}), the open circuit voltage (V_{oc}), and the fill factor (FF), are affected by the slightest change in such design variables, the purity or quality of the chemical pre-cursors, or the specific process flow and fabrication equipment used, and such considerations further complicates the proper specification of design parameters and predicting the efficiency of a proposed design which may appear “on paper” to be advantageous.

It must be further emphasized that in addition to process and equipment variability, the “fine tuning” of minute changes in the composition, band gaps, thickness, and doping of every layer in the arrangement has critical effect on electrical properties such as the open circuit voltage (V_{oc}) and ultimately on the power output and efficiency of the solar cell.

To illustrate the practical effect, consider a design change that results in a small change in the V_{oc} of an active layer in the amount of 0.01 volts, for example changing the V_{oc} from 2.72 to 2.73 volts. Assuming all else is equal and does not change, such a relatively small incremental increase in voltage would typically result in an increase of solar cell efficiency from 29.73% to 29.84% for a triple junction solar cell, which would be regarded as a substantial and significant improvement that would justify implementation of such design change.

For a single junction GaAs subcell in a triple junction device, a change in V_{oc} from 1.00 to 1.01 volts (everything else being the same) would increase the efficiency of that junction from 10.29% to 10.39%, about a 1% relative increase. If it were a single junction stand-alone solar cell, the efficiency would go from 20.58% to 20.78%, still about a 1% relative improvement in efficiency.

Present day commercial production processes are able to define and establish band gap values of epitaxially deposited layers as precisely as 0.01 eV, so such “fine tuning” of compositions and consequential open circuit voltage results are well within the range of operational production specifications for commercial products.

Another important mechanical or structural consideration in the choice of semiconductor layers for a solar cell is the desirability of the adjacent layers of semiconductor materials in the solar cell, i.e. each layer of crystalline semiconductor material that is deposited and grown to form a solar subcell, have similar or substantially similar crystal lattice constants or parameters.

Here again there are trade-offs between including specific elements in the composition of a layer which may result in improved voltage associated with such subcell and therefore potentially a greater power output, and deviation from exact crystal lattice matching with adjoining layers as a consequence of including such elements in the layer which may result in a higher probability of defects, and therefore lower manufacturing yield.

In that connection, it should be noted that there is no strict definition of what is understood to mean two adjacent layers are “lattice matched” or “lattice mismatched”. For purposes in this disclosure, “lattice mismatched” refers to two adjacently disposed materials or layers (with thicknesses of greater than 100 nm) having in-plane lattice constants of the materials in their fully relaxed state differing from one another by less than 0.02% in lattice constant. (Applicant notes that this definition is considerably more stringent than that proposed, for example, in U.S. Pat. No. 8,962,993, which suggests less than 0.6% lattice constant difference as defining “lattice mismatched” layers).

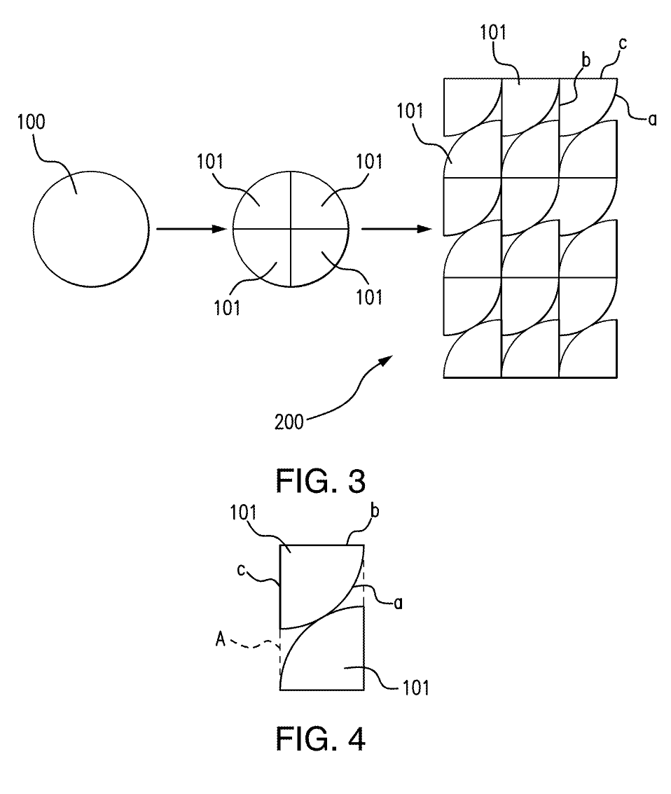

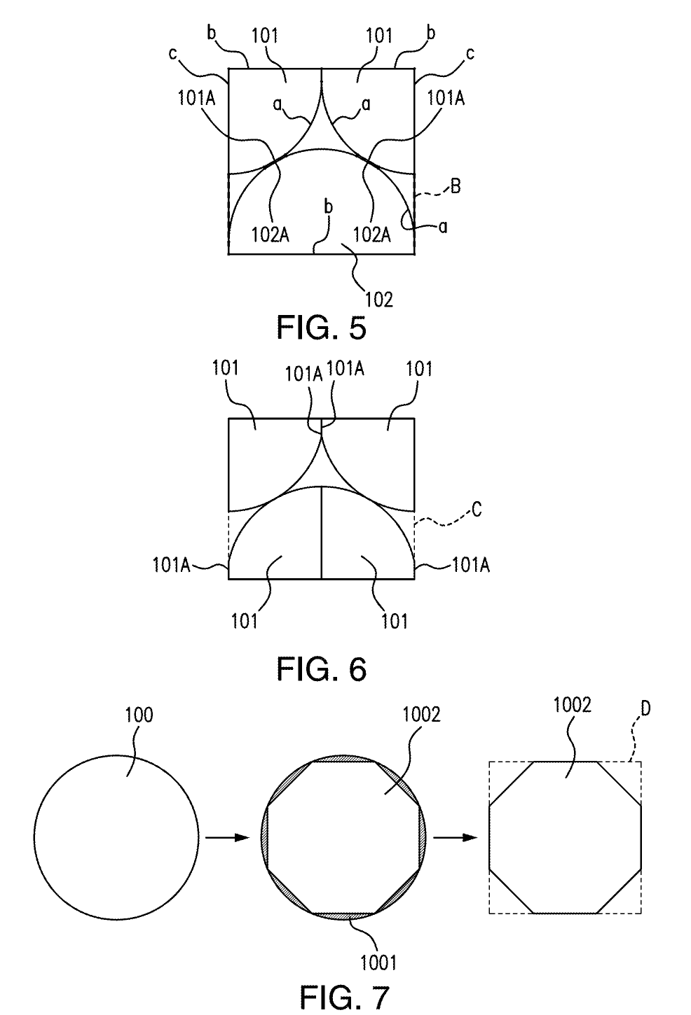

FIG. 3 schematically illustrates how, in accordance with an embodiment of the disclosure, a substantially circular solar cell wafer 100 is divided into four sectors (in the figure, the sectors are quadrants), thus producing four solar cells 101 each having a curved edge a, corresponding to the arc portion of the circumference of the circular wafer 100, and two substantially straight edges b and c extending at a right angle (90 degrees). These solar cells can be packed to form a solar cell assembly 200 as illustrated in FIG. 3, that is, in accordance with a pattern formed by an array of equal rectangles or “unit cells” A (as shown in FIG. 4), these rectangles being arranged adjacent to each other forming an array. Each rectangle encompasses two solar cells 101, fitting efficiently into the area of the rectangle or unit cell A as shown in FIG. 4. These unit cells can fill a rectangular panel or surface with a fill factor of 100%. For example, the solar cell assembly 200 of FIG. 3 comprises an array of 3×3 unit cells of the type shown in FIG. 4. Thus, the fill factor of the solar cells on the panel, that is, the fill factor of the solar cells 101 in the entire solar cell array 200, will be the same as the fill factor of the solar cells 101 in the unit cell A. It has been found that the use of solar cells shaped substantially as quadrants of a circle can at least sometimes be an appropriate solution, taking into account how the quadrants can fit into a rectangular unit cell with a fill factor of about 90% or greater, that is, with a rather high fill factor, cf. FIG. 4. FIG. 5 shows the unit cell B in accordance with an alternative embodiment in which one or more substantially circular wafers have been divided into quadrants and/or halves in order to make three solar cells, one cell corresponding to a semicircle with one curved edge a and one straight edge b, and the other two cells corresponding to quadrants, each with one curved edge a and two straight edges b and c. The use of quadrants only may be beneficial for enhancing the fill factor of the unit cell, but combining semicircular cells and quadrants can be useful to limit the number of interconnections while obtaining a still high fill factor of about 90% or greater. FIG. 5 also shows how in the illustrated embodiment of the invention, in order to additionally improve the fill factor, the solar cells have been provided with straight portions 101A and 102A at their curved edges. These straight portions can correspond to flat portions of the original wafer, or be added by cropping the solar cells to improve the fill factor. In other embodiments of the invention, no such straight portions are present at the curved edges, or only some of the solar cells feature such straight portions at their curved edges.

FIG. 6 shows an arrangement in which the substantially circular wafers out of which the solar cells 101 have been obtained had so-called flats. Semiconductor wafers are often supplied with a portion of the circumference removed; this part is sometimes referred to as the “bottom flat”. During processing, one or more corresponding portions can be removed from part of the circumference, so that there are two or more flat portions. FIG. 6 illustrates how four quadrants obtained from one or more of this kind of wafer can be arranged in correspondence with a rectangular, and in some cases square, unit cell C. The flat portion 101A of each quadrant, that is, the portion corresponding to the flat part of the circumference of the wafer prior to dividing it into multiple solar cells, is placed against the boundaries of the unit cell C or against the flat portion 101A of an adjacent solar cell. This provides for a high fill factor, such as 90% or greater.

FIG. 7 schematically illustrates how a square solar cell with cropped corners 1002 can be produced from a circular wafer 100. FIG. 7 shows how the solar cell 1002 fits into a square unit cell D. As discussed, square unit cells are useful for building assemblies because they can be rotated, simplifying assembly, without disrupting the array pattern. FIG. 7 illustrates how a square unit cell is derived from a square solar cell with truncated corners, which compromises wafer utilization for a square unit cell. Such a compromise is not preferred, because it sacrifices wafer utilization due to the waste 1001 of wafer material, and therefore increases solar cell cost, while achieving a moderate fill factor in the order of 80%. In contrast, the new method described in this disclosure enables >90% wafer utilization and >90% fill factor and, in some embodiments, produces square unit cells, which may be favorable to non-equilateral rectangles. The method described here is therefore preferred, for example, to the one illustrated in FIG. 7, and to other methods of producing rectangular or square unit cells at the expense of wafer utilization or fill factor.

Thus, a space-qualified solar cell assembly is described. For example, a space-qualified solar cell assembly designed for operation at AM0 and at a 1 MeV electron equivalent fluence of at least 5×10¹⁴ e/cm² described, the assembly comprising a III-V compound semiconductor multijunction solar cell including at least three subcells, including a ceria doped borosilicate glass supporting member that is 3 to 6 mils in thickness attached to each solar cell with a transparent adhesive, wherein a combination of compositions and band gaps of the subcells is designed to maximize efficiency of the solar cell at a predetermined end-of-life (EOL) time period, after initial deployment when the solar cell is deployed in space at AM0 and at an operational temperature in the range of 40 to 70 degrees Centigrade, the predetermined EOL time period comprising at least five years. The space-qualified solar cell assembly comprises a plurality of space-qualified solar cells, each space-qualified solar cell of the plurality of space-qualified solar cells being shaped as a portion of a circle, the portion having at least one curved edge having a shape of an arc of a circumference of said circle and at least one straight edge, the portion having a surface area corresponding to not more than 50% of a surface area of said circle.

In another example, a method of producing space-qualified solar cells for a space-qualified solar cell assembly designed for operation at AM0 and at a 1 MeV electron equivalent fluence of at least 5×10¹⁴ e/cm², comprises: forming a III-V compound semiconductor multijunction solar cell including at least three subcells; attaching a ceria doped borosilicate glass supporting member that is 3 to 6 mils in thickness to each space-qualified solar cell with a transparent adhesive; forming a combination of compositions and band gaps of the space-qualified subcells designed to maximize efficiency of the space-qualified solar cell at a predetermined end-of-life (EOL) time period, after initial deployment when the space-qualified solar cell is deployed in space at AM0 and at an operational temperature in the range of 40 to 70 degrees Centigrade, the EOL comprising at least five years; and dividing at least one substantially circular space-qualified solar cell wafer into a plurality of portions, each portion being a space-qualified solar cell, at least some of the portions having at least one substantially straight edge and one substantially curved edge corresponding to an arc of the circumference of the space-qualified solar cell wafer.

In this text, the term “comprises” and its derivations (such as “comprising”, etc.) should not be understood in an excluding sense, that is, these terms should not be interpreted as excluding the possibility that what is described and defined may include further elements, steps, etc.

The disclosure is obviously not limited to the specific embodiment(s) described herein, but also encompasses any variations that may be considered by any person skilled in the art (for example, as regards the choice of materials, dimensions, components, configuration, etc.), within the general scope of the disclosure as defined in the claims.

1. A space-qualified solar cell assembly designed for operation at AM0 and at a 1 MeV electron equivalent fluence of at least 5×10¹⁴ e/cm², the assembly comprising a III-V compound semiconductor multijunction solar cell including at least three subcells, including a ceria doped borosilicate glass supporting member that is 3 to 6 mils in thickness attached to each solar cell with a transparent adhesive, wherein a combination of compositions and band gaps of the subcells is designed to maximize efficiency of the solar cell at a predetermined end-of-life (EOL) time period, after initial deployment when the solar cell is deployed in space at AM0 and at an operational temperature in the range of 40 to 70 degrees Centigrade, the predetermined EOL time period comprising at least five years, the space-qualified solar cell assembly comprising a plurality of space-qualified solar cells, each space-qualified solar cell of the plurality of space-qualified solar cells being shaped as a portion of a circle, the portion having at least one curved edge having a shape of an arc of a circumference of said circle and at least one straight edge, the portion having a surface area corresponding to not more than 50% of a surface area of said circle.

2. The space-qualified solar cell assembly of claim 1, wherein the curved edge of the plurality of space-qualified solar cells has a length corresponding to at least 45 degrees, preferably at least 60 degrees, more preferably at least 90 degrees, and up to 180 degrees of the circumference of the circle.

3. The space-qualified solar cell assembly according to claim 1, wherein the plurality of space-qualified solar cells are substantially shaped as sectors of circles.

4. The space-qualified solar cell assembly of claim 3, wherein the plurality of space-qualified solar cells comprises a plurality of space-qualified solar cells substantially shaped as quadrants of circles.

5. The space-qualified solar cell assembly of claim 3, wherein the plurality of space-qualified solar cells comprises a plurality of space-qualified solar cells shaped as semicircles.

6. The space-qualified solar cell assembly of claim 3, wherein the plurality of space-qualified solar cells comprises a plurality of space-qualified solar cells shaped as semicircles and quadrants of circles.

7. The space-qualified solar cell assembly of claim 1, wherein a plurality of the space-qualified solar cells are arranged so that a straight edge of one space-qualified solar cell is placed against the straight edge of another one of the space-qualified solar cells.

8. The space-qualified solar cell assembly of claim 1, wherein the space-qualified solar cells are arranged in a pattern formed by an array of rectangular unit cells, each unit cell encompassing a substantially identical arrangement of at least two space-qualified solar cells.

9. The space-qualified solar cell assembly of claim 8, wherein each unit cell encompasses at least two space-qualified solar cells arranged so that the curved edge of each one of said space-qualified solar cells is placed against the curved edge of another one of said space-qualified solar cells.

10. The space-qualified solar cell assembly of claim 8, wherein each unit cell encompasses at least two space-qualified solar cells arranged so that a flat portion at a curved edge of one space-qualified solar cell is placed against a flat portion at a curved edge of another one of said space-qualified solar cells.

11. The space-qualified solar cell assembly of claim 1, wherein the space-qualified solar cells have been obtained by dividing one or more substantially circular wafers into a plurality of substantially identical portions, such as substantially identical sectors.

12. A method of producing space-qualified solar cells for a space-qualified solar cell assembly designed for operation at AM0 and at a 1 MeV electron equivalent fluence of at least 5×10¹⁴ e/cm², comprising:
forming a III-V compound semiconductor multijunction solar cell including at least three subcells;
attaching a ceria doped borosilicate glass supporting member that is 3 to 6 mils in thickness to each space-qualified solar cell with a transparent adhesive;
forming a combination of compositions and band gaps of the space-qualified subcells designed to maximize efficiency of the space-qualified solar cell at a predetermined end-of-life (EOL) time period, after initial deployment when the space-qualified solar cell is deployed in space at AM0 and at an operational temperature in the range of 40 to 70 degrees Centigrade, the EOL comprising at least five years; and
dividing at least one substantially circular space-qualified solar cell wafer into a plurality of portions, each portion being a space-qualified solar cell, at least some of the portions having at least one substantially straight edge and one substantially curved edge corresponding to an arc of the circumference of the space-qualified solar cell wafer.

13. The method of claim 12, wherein said portions are sectors of the circular space-qualified solar cell wafer.

14. The method of claim 13, wherein said sectors are quadrants of circles or are semicircles or both.

15. A method of producing a space-qualified solar cell assembly, comprising the steps of providing a plurality of space-qualified solar cells with the method of claim 12, and assembling said space-qualified solar cells to provide a substantially rectangular space-qualified solar cell assembly.

16. The method of claim 15, comprising the step of arranging the space-qualified solar cells according to a pattern of identical rectangular unit cells arranged in an array forming the substantially rectangular space-qualified solar cell assembly, each unit cell including an identical arrangement of at least two space-qualified solar cells.

17. The method of claim 15, wherein the space-qualified solar cells are substantially identical.
